(19) United States
(12) Patent Application Publication
(10) Pub. No.: US 2020/0194225 A1
(43) Pub. Date: Jun. 18, 2020

(54) ELECTRON BEAM ANALYSIS

(71) Applicant: GKN Aerospace Services Limited, Redditch, Worcestershire (GB)

(72) Inventor: Yuxing Cui, Redditch, Worcestershire (GB)

(21) Appl. No.: 16/608,930

(22) PCT Filed: May 4, 2018
(86) PCT No.: PCT/EP2018/061588

§ 371 Date: Oct. 28, 2019

(30) Foreign Application Priority Data
May 8, 2017 (GB) 1707327.1

(51) Int. Cl. H01J 37/305; B29C 64/153

(52) U.S. Cl. CPC H01J 37/305; B33Y 30/00; B29C 64/153

(57) ABSTRACT

Performance of a cathode of an electron beam melting machine can be monitored, wherein detection means such as a near infrared (NIR) camera is used in combination with the electron beam of the machine to detect changes in performance over time the machine.

### CROSS-REFERENCE TO RELATED APPLICATIONS

This application is a national stage of, and claims priority to, Patent Cooperation Treaty Application No. PCT/EP2018/061588, filed on May 4, 2018, which application claims priority to Great Britain Application No. GB 1707327.1, filed on May 8, 2017, which applications are hereby incorporated herein by reference in their entireties.

### BACKGROUND

Electron beam melting (EBM) is one of a range of additive manufacturing (AM) processes which allow metal components to be formed or ‘printed’ into a final shape. AM techniques either significantly reduce, or completely negate, the need for machining components from blocks or ‘billets’ of material.

The EBM process involves using an electron beam to heat and melt discrete portions or regions of a bed of powdered metal. Three dimensional coordinates are fed into an EBM machine which uses the data to control the heating process so as to melt or sinter particular portions of the powdered metal bed. This allows a component to be built up in a series of layers, each layer melted to and homogeneous with the preceding layer. EBM allows components to be formed with excellent structural integrity and in complex geometries.

The EBM process is time consuming in the sense that the electron beam must travel in a predetermined manner to build up the required rows and layers. Once a layer is complete the bed of powdered metal is lowered, a fresh layer of powder is laid down and the machine begins to create the next layer. Depending on the size and complexity of the component the manufacturing process can be quite lengthy, for example in the order of a few days.

The electron beam is emitted from an electron beam source within the EBM machine, the electron beam source comprising, for example, a cathode. The cathode may be of the ‘hot tungsten filament’ type, or the more modern ‘single crystalline’ type such as the lanthanium hexaboride LaB6 which offers a longer life, a low work function highly focused beam. The electron beam source, such as for example a tungsten cathode, can generate a stream of high energy electrons. In use, the electrons are provided with sufficient energy to melt the powder metal to form a portion of the desired component. As the cathodes age performance and output energy levels can deteriorate and become unstable. Provided the energy level and control of the cathode is within acceptable boundaries the melting process is unaffected and components can still be formed. A conventional electron beam melting machine also comprises an anode for cooperating with the cathode to generate the electron beam. The anode does not degrade in the same manner as the cathode, and any degradation of the anode is insignificant relative to the degradation of the cathode. As such, whilst the degradation of the anode can be monitored, the degradation of the cathode is considered to represent the overall performance of the electron beam melting machine.

Over time it is widely known that cathodes degrade and the electron beam output and beam focus typically becomes more erratic and less predictable. In conventional EBM machines, with time the cathodes begin to degrade and control of the beam becomes more difficult.

Degradation of the cathode has been found to cause manufacturing inconsistencies, for example a lack of fusion/porosity and or delamination in the components being manufactured. This may for example be due to the loss of control over the direction and energy delivered by the electron beam. These effects are caused by insufficient energy density during the manufacturing or ‘build’ process. Eventually it is necessary for the cathodes to be replaced so as to maintain homogenous components with the required structural properties. Such cathode degradation results in a build area, which is a surface on which the electron beam is directed to and on which a component being ‘built’ is formed, being affected in a non-uniform manner. For example, when the cathode degradation starts to occur, the periphery of the build area may be more significantly affected than the centre of the build area.

A defective cathode can result in defective components, and establishing whether a component is defective can be done in a number of ways.

In order to identify any irregularities in the finished components (which would indicate the need to change the cathode) a number of approaches are used. One approach is to form a number of sacrificial test bars which can then be tested in, for example, a tensile testing machine. Other non-destructive testing techniques include computed tomography (CT) scans or X-ray analysis which can identify defects or irregularities in the material that has been produced by the EBM process.

However, each of these techniques can only be used after the component has been produced by the EBM machine. As discussed above, the process can take many hours depending on the complexity of the component. Thus, it is only possible to establish if there is a problem with the EBM process (for example a defective cathode) after the process is complete. This can delay manufacturing significantly since if a defect is detected the component must be discarded and the EBM process started again.

### SUMMARY

Presently disclosed and claimed is a novel way to identify defects or irregularities in EBM manufactured components during the manufacturing process, thus allowing any malfunction of the EBM machine to be identified immediately.

Viewed from a first aspect there is provided a method of monitoring the performance of an electron beam melting machine, the electron beam melting machine comprising a chamber, an electron beam source, an electron beam source directing apparatus, the chamber further comprising a reference surface against which the electron beam can direct a beam of electrons, the machine further comprising a detector arranged to detect the excitation of portions of the reference surface in response to a beam of electrons, the method comprising the steps of:
activating the electron beam source to project a beam of electrons onto the reference surface at a plurality of predetermined measurement points;
detecting the excitation of the at least a portion of the reference surface at each of said predetermined measurement points; and
comparing the detected excitation at each of said predetermined measurement points with predetermined excitation data for the electron beam source at each of the predetermined measurement points to detect a change in performance of the electron beam source.

If the output energy level and output characteristics of the cathode deteriorate too much, the resulting melting process can be adversely affected to such an extent that internal abnormalities are created within the three dimensional component being formed. As discussed above, conventionally these abnormalities can only be identified after the component has been completed using, for example, X-ray imaging to look inside the component.

The present disclosure identifies an alternative way in which the electron beam itself can be used in combination with a particular camera arrangement and data processor to identify any deterioration in cathode performance. Advantageously, and importantly, this assessment can be before a component is built, i.e., a determination is made before any machine time is used in making a component as to whether the cathode, and thus the electron beam melting machine, is able to operate within acceptable performance limits.

Specifically, an electron beam melting (EBM) machine is provided with a detector that can be used to detect the energy level and control of the cathode creating the electron beam. Advantageously, a near infrared camera may be used which is arranged in use with a view of the build plate of the EBM.

The reference surface may advantageously be the build plate which is already housed within an EBM machine. This is a substantially flat surface on which the component being ‘built’ is created. The build plate advantageously provides a reference surface within the machine which can be used for the assessment of the present invention. During the ‘build’ or forming process in the EBM the electron beam creates high energy electrons which are directed at the metal powder which is spread across the build plate.

However, it has now been established that the cathode, in combination with the build plate (before metal powder has been applied) may act as a convenient test arrangement to detect changes in performance of the cathode over time.

The electron beam is activated to direct electrons onto the build plate surface. The build plate absorbs electron energy causing excitation of portions of the build plate that are exposed to the electron beam. This excitation (in the form of heat) can be detected providing an indication of how much energy the electron beam is distributing over each predetermined area of the build plate surface. By detecting the excitation of the build plate at predetermined measurement points and comparing the results with predetermined excitation data for the cathode at each of the predetermined measurement points it is possible establish how the energy the cathode is releasing changes over time.

By comparing any new data against a predetermined threshold it is possible to determine before the cathode is used for a build if the cathode will be able to evenly distribute sufficient energy to cause the metal powder to melt properly. The predetermined threshold may be selected according to the application, for example how critical the part is in use and what post-processing will be undertaken.

Thus, the present disclosure provides a way to confirm the operability of the cathode in the EBM before time and material are consumed in a new build.

The build plate may advantageously be substantially flat to provide a flat surface on which the component can be build. The cathode may be located so as to oppose the centre of the build plate to so as to be able to expose all of the build plate to a stream of electrons.

In order to accurately detect changes in the cathode performance, the excitation caused by the electron beam must be measured repeatedly at the same points, i.e., predetermined measurement points. The predetermined measurement points at which the electron beam is directed may be a matrix of evenly spaced points across the build plate. For example, the matrix may be in the form of a rectilinear matrix of points. This advantageously allows the excitation energy to be determined across at least part of the build plate. The predetermined measurement points may be across the entire surface of the build plate, in which case the excitation energy can be determined across the entire surface of the build plate. Thus, the function of the cathode can be assessed for all points where building (melting) might occur. This further allows the arrangement to detect any anomalies (dead spots) where electron beam energy in defective

The electron beam direction may be controlled so that the electron beam is directed at each of the plurality of predetermined measurement points in a predetermined sequence until all of the measurement points have been exposed to the electron beam. This sequence is repeated for each cathode assessment so that like-for-like data is compared to accurately monitor changes in performance of the cathode.

For example, the matrix may comprise a plurality of rows, each row comprising a plurality of measurement points and wherein each point in a row is exposed before the next adjacent row is exposed until all measurement points have been exposed. In effect the cathode beam raster scans across the surface of the build plate.

The energy that is required to excite the build plate is lower than the energy required to cause melting of the metal powder during a build and thus the cathode may be controlled to emit lower energy electrons during the testing of the cathode. Alternatively, normal melting energy levels may be used but exposure to the measurement points on the build plate reduced to cause excitation (for measurement) but not melting of the build plate. For example each measurement point may be exposed for less than 1 millisecond, for example 0.25 milliseconds.

The cathode may be controlled to deliver a predetermined excitation energy to each measurement point. For example, such predetermined excitation energy may be 30 milli-joules. There may be a suitable range of predetermined excitation energy depending on the powdered material used. For a base plate made of steel, for example, excitation energy level may be in the range of from 0.1 milli-joules to 100 milli-joules.

The step of detecting the excitation caused by the electron beam emitted from the cathode may be by any suitable detector capable of detecting the effect the electron beam has on the build plate (indicating cathode performance). Advantageously, a near infrared (NIR) camera may be used as the detector. Alternatively, an infrared or even a normal range camera could be used.

Such an NIR camera may be positioned adjacent to the cathode and directed towards the build plate. The camera may be active whilst the excitation of each measurement points to capture an image of the build plate for each measurement points. Multiple images may be taken for each measurement points for one of the image to be chosen for the final overall image of the build plate which combines the image of each measurement points. The image, from the infrared wavelength, will contain data indicative of how much the build plate has been heated at each of the measurement points. In other embodiments, the camera may be deactivated and re-activated during each time a measurement point is excited to capture an image, or be activated to take an image of the build plate once the cathode has been deactivated having excited each of the measurement points.

The greater the excitation the electron beam has caused, the greater the heat at the measurement point and the greater the infrared intensity of the image at each measurement point. Thus, there is a correlation between the infrared signals the NIR camera creates and the excitation energy of the cathode. It is this correlation which can be processed to determine changes in cathode performance as described further below.

The NIR camera could be an ‘off-the-shelf’ product arranged to operate in the range of 350 nm to 1050 nm wavelength. The output from the camera is a standard image output capable of being processed by conventional image equipment.

For example, the data may be received from the camera by a data storage and processing arrangement. The data storage (a hard disc drive for example) may store predetermined or historical excitation/brightness data for the cathode of the machine. This allows the current data which is received from the camera to be compared with either (a) predetermined data which is data indicating acceptable excitation data for a functioning cathode and/or (b) historical data for the given cathode illustrating any changes in excitation caused by the electron beam at each measurement point. The data may be compared with any suitable computing device.

The arrangement may advantageously be calibrated so that the NIR data from the camera can be converted into electron beam energy data which can then be compared against acceptable energy output for a given metal powder to be melted.

Thus, the operator of the EBM machine is able to determine before the build if the cathode will distribute an appropriate energy level across the build plate. It may further be determined if the cathode is not providing a uniform energy level across the build plate thus allowing the operator to build only where it is established that the cathode is functioning sufficiently well.

The data processing of the NIR data may be done locally within or proximate the machine. The cathode measurement loop may for example be performed as part of the machine initialisation and routinely performed before each build or during the build, for example where a new powder layer is configured to act as the base plate. For example, a measurement may be conducted during the build by default after every predetermined amount of time or after predetermined events. Such predetermined events may for example be occurrence of smoke or arc trips. The machine may advantageously include a graphical user interface configured to display a signal or image indicating the performance of the cathode. Historical data may also be simultaneously displayed.

Alternatively the processing may be performed remotely, for example at the EBM machine manufacturer where maintenance can be provided according to determinations made about the performance of the cathode.

Advantageously changes in cathode performance may be monitored over a period of time to establish a trend in diminishing performance. Thus, the point at which the cathode fails to work adequately may be predicted and pre-emptive maintenance to replace the cathode taken to optimise machine performance.

Viewed from another aspect there is provided an electron beam melting machine arranged in use to operate according to a method as described herein.

Viewed from yet another aspect there is provided an electron beam melting machine comprising a vacuum chamber, electron beam source, an electron beam source directing apparatus, the chamber further comprising a build plate against which the electron beam can direct a beam of electrons, the machine further comprising a camera arranged to measure the brightness at discrete points on the build plate in response to a beam of electrons.

As described above the detector or camera may be any suitable device which can collect data from the build plate (without contact with the build plate) indicating how the build plate has been excited by the electron beam.

For example a camera may be used and located within the vacuum chamber in close proximity to the cathode and build plate. Alternatively the camera may be located outside of the vacuum chamber with a window or the like allowing the camera to ‘see’ the build plate inside the vacuum chamber.

### BRIEF SUMMARY OF THE DRAWINGS

Further description will be provided, by way of example only, with reference to the accompanying figures in which:

FIG. 1 shows schematic of an electron beam melting process;

FIG. 2 shows multiple layers of an electron beam melting product being formed;

FIG. 3 shows a typical cathode that may be used in conjunction with the present disclosure;

FIGS. 4A and 4B show a new cathode and degraded cathode respectively;

FIG. 5 is a schematic of a modified electron beam melting machine according to an embodiment;

FIG. 6 illustrates the measurement points in a matrix arrangement;

FIG. 7 shows a graphical representation of the brightness data received from the NIR camera;

FIG. 8 shows a plan view of the data shown in FIG. 7; and

FIG. 9 shows a graphical representation of the brightness data received from the NIR camera where the cathode is degraded.

While the invention is susceptible to various modifications and alternative forms, specific embodiments are shown by way of example in the drawings and are herein described in detail. It should be understood however that the drawings and detailed description attached hereto are not intended to limit the invention to the particular form disclosed but rather the invention is to cover all modifications, equivalents and alternatives falling within the spirit and scope of the claimed invention

It will be recognised that the features of the aspects of the invention(s) described herein can conveniently and interchangeably be used in any suitable combination

### DETAILED DESCRIPTION

The operation of an electron beam melting (EBM) machine will be well understood by a person skilled in the art of additive manufacturing.

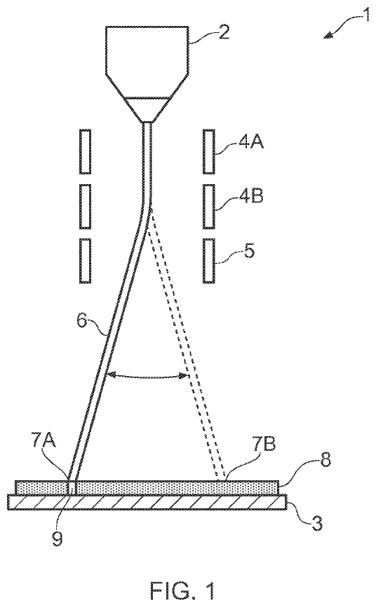

FIG. 1 shows a schematic of an electron beam melting machine illustrating the basic principle. The machine 1 has an electron generating cathode 2 which is located within a vacuum chamber (not shown). It is noted that whilst referred to as a “vacuum chamber” here in accordance with known terminology in the field, the chamber may not in practice be completely a vacuum. For example, the “vacuum chamber” may in practice include a low quantity of helium or argon. Such “vacuum chamber” may also be referred to as a “low pressure chamber”. The cathode is arranged to oppose a build plate or surface 3 which is a substantially flat surface, typically formed of steel surface which the three dimensional components are built upon (described in more detail below).

Immediately adjacent to the outlet of the cathode are a plurality of magnetic lenses which generate a magnet field when energised. In the embodiment shown 3 lenses are provided although any number may be used. In the embodiment shown the first two lenses 4A and 4B are ‘shaping’ lenses and are energised to bring the electron beam into a single beam which can then be directed or ‘aimed’. The final lens 5 is a directing lens and is selectively energised by a controller (not shown) to control the direction of the electron beam 6.

Selectively controlling the electron beam 6 by means of the plurality of magnetic lenses 4A, 4B and 5 allows the beam to be directed to different parts of the build plate 7A, 7B.

In normal operation successive layers of metal powder 8 are laid first on the build plate and then on successive layers of powder. The cathode is controlled to deliver a predetermined amount of energy to generate a beam of electrons with sufficient power to melt the metal powder. Reference 9 illustrates a melted portion of the powder.

The electron beam 6 is controlled by means of the magnetic lenses to ‘print’, which means to build up through electron beam melting additive manufacturing process, the desired component by repeatedly melting tracks of metal powder.

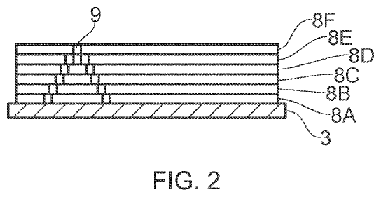

FIG. 2 illustrates how successive layers (8A to 8F) are laid on top of each other to form the complex geometry of the 3 dimensional shape to be built. Although appearing to be relatively thick with respect to the build plate 3 in FIG. 2 each successive layer is in fact 50 to 90 microns thick.

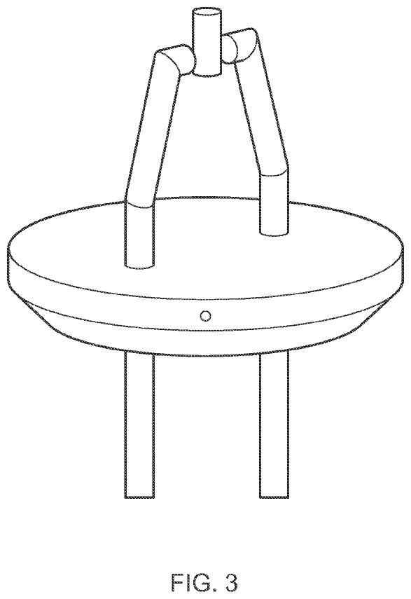

FIG. 3 shows a typical cathode used to emit an electron beam. For example, the cathode may be an LaB6 single crystal cathode.

The cathode slowly deteriorates over time and becomes less reliable in terms of the control of the direction of the electron beam, which is to say the direction of the emitted electrons, and also in terms of the energy that the cathode can emit.

Both direction and energy control are essential in manufacturing components accurately and to the desired structural integrity.

For example, loss of control of the shape of the beam can prevent accurate geometries of components being achieved. Here, the shape of the beam refers to an intensity profile of the beam. Loss of control of energy distribution of the electron beam can cause imperfections in the built components due to lack of fusion (LOF) of the metal powder. LOF will be recognised as the situation where the powder does not melt properly meaning that the layer being built is not homogenous with the preceding layer.

LOF can result in imperfections, voids or distortion within the component being built and/or on the surfaces of the part. Such imperfections can be hazardous, particularly in the aerospace industry where components are manufactured to a high mechanical standard and require complete structural integrity.

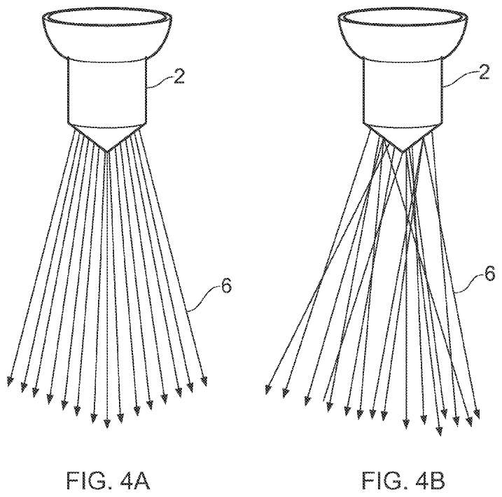

FIGS. 4A and 4B illustrate degradation of an LaB6 cathode.

FIG. 4A shows a new cathode 2 in which the electron beam 6 emission is uniform. This allows for accurate control.

Conversely, FIG. 4B shows an example representation of a degraded cathode 2. Degradation may be a result of a faulty cathode or a cathode that has simply degraded over time. As shown in FIG. 4B the distribution of electrons is irregular and non-uniform. This is known as electron emittance.

When electron emittance is high the magnetic lenses shown in FIG. 1 are unable to accurately control the beam. This not only means that accurate geometries cannot be produced by it means the energy which is delivered at the point where the electron beam meets the metal powder cannot be accurately controlled.

When cathode degradation becomes too great the cathode must be replaced. However, as described above it has only been previously possible to establish if the cathode is failing once a component has been built, for example using destructive techniques or non-destructive technique (NDT) such as X-ray analysis of CT scans. If it is established that a component has suffered, for example, an LOF during build the component must be discarded and re-built. This wastes valuable manufacturing time and resource.

A solution to this problem will now be described.

The cathode 2 is used in combination with the build plate 3 and a detecting camera to create an integrated cathode assessment system within the EBM machine.

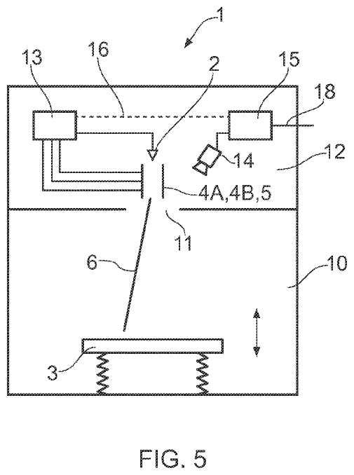

Referring to FIG. 5, the EBM machine is adapted to incorporate a near infrared camera.

The EBM machine comprises a vacuum chamber 10 in which the build plate 3 is located and movable vertically to receive each successive layer (the EBM process is, as set out above, well understood by a person skilled in additive manufacturing techniques).

An upper portion of the machine 1 comprises an aperture 11 connecting the vacuum chamber with the cathode and camera housing 12. The housing 12 comprises the cathode 2 and lens arrangements 4A, 4B and 5. In use the electron beam 6 is directed from the cathode to the base plate 3. A conventional EBM control arrangement 13 controls the cathode and the beam direction using the lenses in a conventional manner.

The EBM machine is also provided with a NIR camera 14 which is arranged with a line of sight of the build plate 3 through the aperture 11.

The camera includes a controller 15 to receive data from the NIR camera. The NIR camera is a conventional camera as known by those skilled in the art. The lens of the camera is directed at the build plate and the camera is configured to receive near infrared wavelengths from the build plate as described below. The camera controller is arranged to either feedback control into the EBM machine controller through control line 16 or externally through port 18.

It will be recognised that the additional components such as heaters, vacuum pumps and powder supply assembly are not shown in FIG. 5 but would be understood by someone skilled in the art.

The cathode assessment or test method will now be described in detail.

Before the build or a component is commenced the EBM machine is taken through a cathode assessment process. This may be performed before each build or after a number of builds. The frequency may for example be increased the older the cathode becomes.

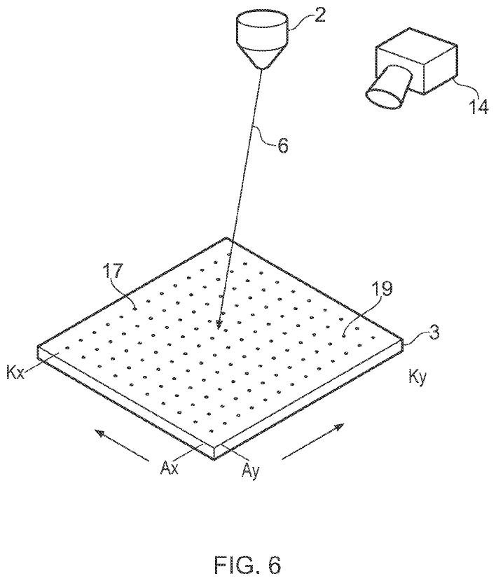

First, a clean un-coated build plate is used as a surface or ‘screen’ against which a cathode test pattern is projected. Specifically, the cathode is activated and the control arrangement used to create a predetermined pattern on the build plate. This is shown by reference 19 in FIG. 6.

The cathode 2 is activated to direct the electron beam at each of the plurality of discrete measurement points 17 forming part of the pattern 19. In the embodiment shown a rectilinear matrix is projected. Any pattern may be used provided it is the same pattern as previously used for continuity purposes (as discussed below).

Each measurement point is excited or illuminated by the electron beam in sequence i.e. the electron beam is configured to travel across the build plate, in the form of raster lines exciting each measurement point in a row (Aₓ to Kₓ) before moving to the next row and exciting each point in the row again. This is repeated until the beam has excited all of the rows A_{y} to K_{y}. It is not essential for the electron beam to travel across in the form of raster lines, and may travel along paths that are, for example, curved, circular, or spiral.

Each point is excited with a power level of 120 watts for 0.25 milliseconds. There may be any number of measurement points but in one embodiment there are 5400 measurement points. These can be excited in 1.3 seconds.

Excitation of the measurement points with the electron beam causes the point to increase in temperature. The result is a matrix of ‘hot spots’ or heater points on the build plate. The more energy applied the more excited and the hotter the measurement point becomes.

During excitation of each measurement point, the NIR camera 14 is activated and takes an image within the near infrared waveband for each excitation of measurement point. A collection of the data and/or images for each of the measurement points provide an overall data and/or image of the reference surface, which in this embodiment is the build plate. Such a camera can ‘see’ or detect the heat radiating from each of the measurement points on the build plate.

The picture that is generated by the NIR camera contains data for each of the measurement points in the picture. This data correlates to how hot the build plate is at each measurement point, which itself correlates to how much energy had been distributed over the predetermined measurement point.

This in turn provides an excitation profile for the cathode i.e. how much energy the cathode has provided in the 0.25 milliseconds the cathode was activated for at each measurement point.

By comparing this data with either predetermined data for a functioning cathode and/or historical data for the particular cathode it is possible to determine if there has been any degradation of the cathode.

This comparison could for example be done manually by viewing current and previous images. If the measurement points are becoming fainter this will indicate a deterioration of energy distribution across the base plate.

However, simple image processing can be applied to determine numerical values for the brightness of each measurement point in the image captured by the NIR camera 14. This can then be compared using a data processor which in turn can calculate trends or rate of degradation. Determining a rate of degradation will allow the processor to predict when energy levels distributed by the given cathode reach a point where melting will no longer satisfactorily be achieved during a build. This allows the cathode to be changed before this point is reached.

This notification could for example be by means of a count-down on the interface of the EBM machine or an alarm or indicator.

Additionally or alternatively, the EBM machine may communicate this information to a central maintenance organisation who could schedule replacement of the cathode before the cathode stopped production.

The person skilled in the art will recognise that one of the factors in deciding if a cathode must be changed is when the cathode can no longer cause effective and acceptable melting of the metal powder. The melting temperature will vary and so the EBM machine may be provided with a user interface allowing the melting temperature to be inputted into the machine which in turn may be used to determine whether the cathode can successfully complete the build with the required energy levels.

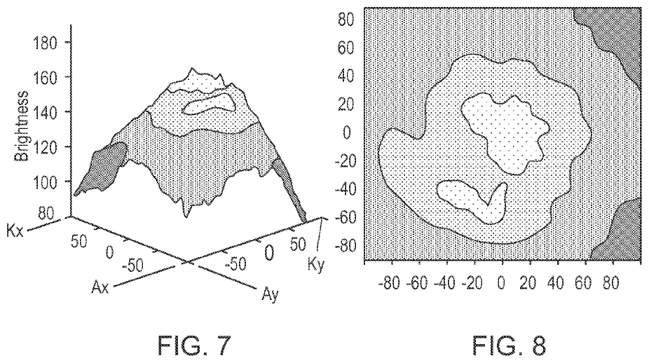

FIG. 7 shows a graphical representation of the data received from the camera with the base axes corresponding to the axes shown in FIG. 6, i.e., the measurement point positions on the matrix. The vertical axis shows the brightness measured at each point. As shown a generally dome shape shows that greater brightness, i.e., better focused energy was delivered to the middle portion of the build plate. This is expected since this will be closer to the electron beam cathode. Outlying measuring points are further away and therefore energy will reduce with a radius squared factor thus having reduced brightness at the perimeter of the build plate.

FIG. 8 is a corresponding vertical view of the data with lighter pixels indicating brighter measurement points.

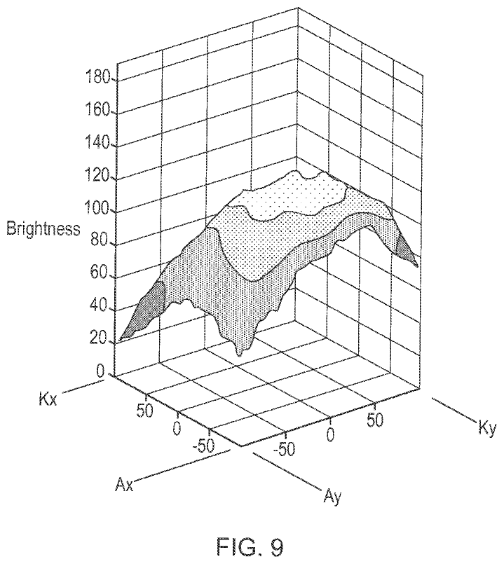

FIG. 9 shows a graphical representation of the data received from the camera with the base axes corresponding to the axes shown in FIG. 6 and thus also corresponding to the axes shown in FIG. 7. In contrast to the substantially dome shape which can be seen in FIG. 7, a deformed dome shape can be seen in FIG. 9. This deformed dome shape is produced based on the data obtained when using a degraded cathode.

The embodiment described above allowed for testing of the cathode between builds, i.e., before a build had been commenced. This involved using the build plate as the surface against which the electron beams are directed in the matrix profile.

In another embodiment an electron beam melting machine may further comprise a reference surface within the vacuum chamber which may for example be selectively movable. For example the surface could be moveable into a position adjacent the cathode which would allow the matrix profile to be projected during a build. In effect the reference surface acting in the same way as the build plate described in the embodiment above. However, incorporating a reference surface that can be used during a build advantageously allows the cathode to be assessed at any point during a component build.

1.-21. (canceled)

22. A method of monitoring the performance of an electron beam melting machine, the electron beam melting machine comprising a chamber, an electron beam source, and an electron beam source directing apparatus, the chamber comprising a reference surface against which the electron beam can direct a beam of electrons, the machine further comprising a detector arranged to detect the excitation of portions of the reference surface in response to a beam of electrons, the method comprising:
activating the electron beam source to project a beam of electrons onto the reference surface at a plurality of predetermined measurement points;
detecting the excitation of the at least a portion of the reference surface at each of said predetermined measurement points; and
comparing the detected excitation at each of said predetermined measurement points with predetermined excitation data for the electron beam source at each of the predetermined measurement points to detect a change in performance of the electron beam source.

23. The method of claim 22, wherein the reference surface is a build plate of the machine or a layer of powdered metal for melting by the electron beam, and is a substantially flat surface within the chamber onto which electron beams are directed.

24. The method of claim 22, wherein the predetermined measurement points at which the electron beam is directed is in a matrix of evenly spaced points across the build plate.

25. The method of claim 24, wherein the matrix is a rectilinear matrix of points.

26. The method of claim 22, wherein the electron beam is directed at each of the plurality of predetermined measurement points in a predetermined sequence until all of the measurement points have been exposed to the electron beam.

27. The method of claim 24, wherein the matrix comprises a plurality of rows, each row comprising a plurality of measurement points and wherein each point in a row is exposed before the next adjacent row is exposed until all measurement points have been exposed.

28. The method of claim 22, wherein the cathode is arranged to deliver a predetermined excitation energy to each measurement point.

29. The method of claim 28, wherein the predetermined excitation energy is within a range of 0.1 milli-joules to 100 milli-joules.

30. The method of claim 22, wherein the electron beam melting machine further comprises a camera directed towards the build plate and arranged in use to face the measurement points.

31. The method of 30, wherein the camera is a near infra-red (NIR) camera capable of detecting wavelengths of between 350 nm to 1050 nm.

32. The method of claim 30, wherein the camera is arranged to output brightness data received from the view the camera has of the build plate indicating the excitation caused by the electron beam at each of the measurement points on the build plate.

33. The method of claim 30, wherein data is received from the camera by a data storage and processing arrangement, said arrangement storing predetermined or historical excitation/brightness data for the cathode, and wherein the data received from the camera is compared by the data processing arrangement with said predetermined or historical data to determine changes in performance of the cathode.

34. The method of claim 33, wherein the data processing is performed remotely from the electron beam melting machine.

35. The method of claim 22, wherein the steps are performed before each build in a plurality of builds within the electron beam melting machine to create a record of changing cathode performance within a data store.

36. The method of 35, wherein the excitation/brightness at each measurement point is correlated with an electron beam energy level distributed over the measurement point and compared with a predetermined electron beam energy output level required to melt the powder metal to be used for a build, and wherein, upon determining that the determined energy level at one or more measurement points is at or below the predetermined threshold, an indication is given that the cathode is defective or that the beam is not calibrated correctly.

37. The method of claim 22 wherein the plurality of measurement points are excited by electrons emitted from the cathode for a predetermined period of time at each of the measurement points, wherein the step of detecting the excitation of the build plate at each of said predetermined measurement points is simultaneously performed during excitation of each measurement point.

38. The method of claim 23, wherein monitoring the performance of a cathode of an electron beam melting machine is performed during a build by default after every predetermined amount of time or after predetermined events.

39. An electron beam melting machine comprising a chamber, an electron beam source, and an electron beam source directing apparatus, the chamber comprising a reference surface against which the electron beam can direct a beam of electrons, the machine further comprising a detector arranged to detect the excitation of portions of the reference surface in response to a beam of electrons, the machine arranged for performance of a method that includes:
activating the electron beam source to project a beam of electrons onto the reference surface at a plurality of predetermined measurement points;
detecting the excitation of the at least a portion of the reference surface at each of said predetermined measurement points; and
comparing the detected excitation at each of said predetermined measurement points with predetermined excitation data for the electron beam source at each of the predetermined measurement points to detect a change in performance of the electron beam source.

40. An electron beam melting machine comprising:
a chamber;
an electron beam source;
an electron beam source directing apparatus, wherein the chamber further comprises a build plate against which the electron beam can direct a beam of electrons; and
a camera arranged to measure the brightness at discrete points on the build plate in response to a beam of electrons.

41. The electron beam melting machine of claim 39, wherein the camera is a near infra-red camera (NIR) and wherein the machine is arranged to communicate data from the camera indicating brightness to a data processing arrangement.
